(19) United States
(12) Patent Application Publication
(10) Pub. No.: US 2006/0267168 A1
(43) Pub. Date: Nov. 30, 2006

(54) Hollow package and semiconductor device using the same

(75) Inventors: Takeshi Misawa, Saitama (JP); Atsuhiko Ishihara, Saitama (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/443,285

(22) Filed: May 31, 2006

(30) Foreign Application Priority Data
May 31, 2005 (JP) 2005-160197

(51) Int. Cl. H01L 23/02

(52) U.S. Cl. 257/678

(57) ABSTRACT

A solid state imaging device is composed of an image sensor chip and a hollow package that contains the image sensor chip. The hollow package has a recessed first chip chamber on a top surface of its package body. Formed on a bottom surface of the first chip chamber is a recessed second chip chamber. A small image sensor chip is contained in the second chip chamber, whereas a large image sensor chip is contained in the first chip chamber.

### BACKGROUND OF THE INVENTION

1. Field of the Invention

The present invention relates to a hollow package for containing a semiconductor chip, and relates to a semiconductor device, such as a solid state imaging device, which has the hollow package containing a semiconductor chip.

2. Background Arts

Most of semiconductor devices use a package for containing a semiconductor chip, and input/output pads of the semiconductor chip are connected to leads of the package through bonding wires. One of commonly used packages is a hollow package.

The hollow package is composed of a ceramic or plastic made box-like package body whose top surface is provided with a recessed chip chamber for containing a semiconductor chip, leads inserted in the package body, and a cover attached on the package body to seal the chip chamber. Instead of the bonding wires, bumps are often used recently. If the semiconductor chip is an image sensor chip such as a CCD image sensor or a CMOS image sensor, the cover is made of a transparent material such as glass.

An output signal-to-noise ratio of the image sensor chip is impaired by, for example, heat generated during the operation. Accordingly, various methods for dissipating heat of the image sensor chip have been proposed. One known method among them is to give a heat radiation function to the hollow package. For example, the U.S. patent application publication No. 2001/0052640 (corresponding to the Japanese patent laid-Open Publication No. 2001-257330) and the Japanese patent laid-open publication No. 2004-146530 disclose the hollow packages both of which have a lead frame integrated with a heat conductive member that makes contact with the under surface of the image sensor chip and a radiation member exposed outside the package. Also, the Japanese patent laid-open publication No. 2003-007880 discloses the hollow package having metal plates attached to top and under surfaces of a lead frame for radiation.

Usually, the hollow package is tailored to the size of the semiconductor chip that is going to be contained, and hardly accommodates the semiconductor chip of another size. In order to reduce the cost of the semiconductor devices, however, there is a demand for the hollow package to contain the semiconductor chips of different sizes.

In addition, since the above disclosed hollow packages use metal components for radiation of the image sensor chips, accompanying increases in the number of components, the number of works, and the cost are also problems.

### SUMMARY OF THE INVENTION

In view of the foregoing, a primary object of the present invention is to provide a hollow package which can contain semiconductor chips of different sizes.

Another object of the present invention is to provide a low cost and simple structured hollow package which can dissipate heat of the semiconductor chip.

Still another object of the present invention is to provide a low cost semiconductor device with excellent heat radiation effect.

To achieve the above and other objects, the hollow package according to the present invention includes a package body having first and second chip chambers, connectors electrically connected to a semiconductor chip, and a cover attached on a top surface of the package body to seal the first chip chamber. The first chip chamber is formed on the top surface of the package body, whereas the second chip chamber is formed on a bottom surface of the first chip chamber. A large semiconductor chip is contained in the first chip chamber. A small semiconductor chip is contained in the second chip chamber.

When the large semiconductor chip is contained in the first chip chamber, a heat conductor is contained in the second chip chamber. This heat conductor transmits heat of the semiconductor chip to a bottom surface of the second chip chamber. Preferably, the heat conductor is a defective semiconductor chip. The use of the otherwise-discarded defective semiconductor chip allows to reduce the cost, and wastes as well.

Additionally, it is possible to form a through hole that penetrates to the bottom surface of the second chip chamber. In this case, a heat conductive member is inserted into the through hole and attached to the semiconductor chip or the heat conductor, and thereby the heat radiation effect is improved.

A semiconductor device of the present invention incorporates the above described hollow package. The cost of the semiconductor device, such as a solid state imaging device, is therefore reduced. In addition, the heat radiation effect of the semiconductor device is improved.

According to the present invention, it is possible to reduce the cost of the hollow package and the semiconductor device. Furthermore, the heat of the semiconductor chip is dissipated effectively.

### BRIEF DESCRIPTION OF THE DRAWINGS

For more complete understanding of the present invention, and the advantage thereof, reference is now made to the following descriptions taken in conjunction with the accompanying drawings, in which:

FIG. 1 is a cross sectional view of a solid state imaging device with a small image sensor chip in a hollow package;

FIG. 2 is a cross sectional view of the solid state imaging device with a large image sensor chip in the hollow package;

FIG. 3 is a cross sectional view of the solid state imaging device with the large image sensor chip and a heat conductive plate in the hollow package;

FIG. 4 a cross sectional view of the solid state imaging device with the large image sensor chip and the heat conductive plate in the hollow package, whose package body has a through hole on the under surface.

### DESCRIPTION OF THE PREFFERED EMBODIMENTS

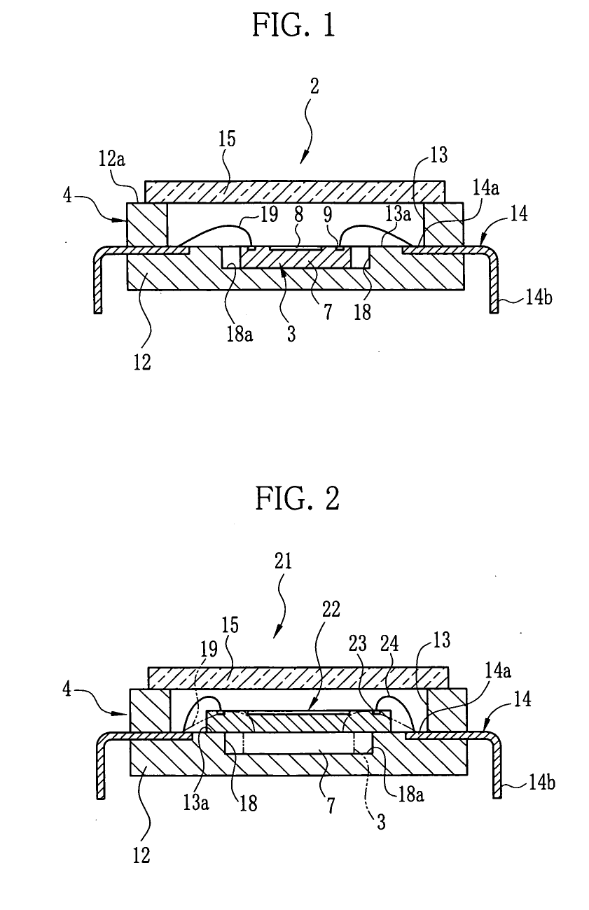

Referring to FIG. 1, a solid state imaging device 2 includes an image sensor chip 3, and a hollow package 4 for containing the image sensor chip 3. The image sensor chip 3, such as a CCD image sensor chip or a CMOS image sensor chip, is composed of a light receiving area 8 and plural input/output pads 9 formed on the top surface of a chip substrate 7 made of silicon or the like. The light receiving area 8 has a plurality of, for example, photodiodes (PD) arranged in a matrix form, and color filters and the micro-lenses (both not shown) are placed above the photodiodes. The input/output pads 9 are electrode pads made of a conductive metal material, and electrically connected to the light receiving area 8.

The hollow package 4 includes a box-like package body 12 made of ceramics or plastics, a recessed first chip chamber 13 formed on a top surface 12a of the package body 12, metal leads 14 inserted in the package body 12, and a cover 15 attached on the top surface 12a of the package body 12 to seal the first chip chamber 13. One end of each lead 14, which is electrically connected to the image sensor chip 3, forms an inner lead portion 14a exposed inside the first chip chamber 13, and the other end of the lead 14 forms an outer lead portion 14b extending outside the package body 12. In the solid state imaging device 2, the cover 15 is made of a transparent glass plate or plastic plate so that light will enter the image sensor chip 3.

Formed on a bottom surface 13a of the first chip chamber 13 is a recessed second chip chamber 18. The image sensor chip 3 is smaller than the second chip chamber 18, and die-bonded on a bottom surface 18a of the second chip chamber 18. The input/output pads 9 of the image sensor chip 3 are then connected to the inner lead portions 14a of the leads 14 through bonding wires 19, and the first chip chamber 13 is sealed with the cover 15.

As shown in FIG. 2, an image sensor chip 22 which is larger than the second chip chamber 18 is die-bonded on the bottom surface 13a of the first chip chamber 13. Input/output pads 23 of the image sensor chip 22 are then connected to the inner lead portions 14a of the leads 14 through bonding wires 24. Instead of the bonding wires 24, bumps may be used to connect the image sensor chip 22 with the leads 14.

Since the second chip chamber 18 of small size is formed in the first chip chamber 13 as described, the hollow package 4 can accommodate the image sensor chips 3 and 22 of different sizes. Therefore, the cost of the solid state imaging device 2 is reduced.

It is noted that, as shown in FIG. 2, the second chip chamber 18 becomes empty when the image sensor chip 22 is die-bonded on the bottom surface 13a of the first chip chamber 13. This empty space impedes the heat conduction between the image sensor chip 22 and the package body 12, and results in lowering the heat radiation effect. If the image sensor chip 22 rises in temperature, its output signal-to-noise ratio is impaired.

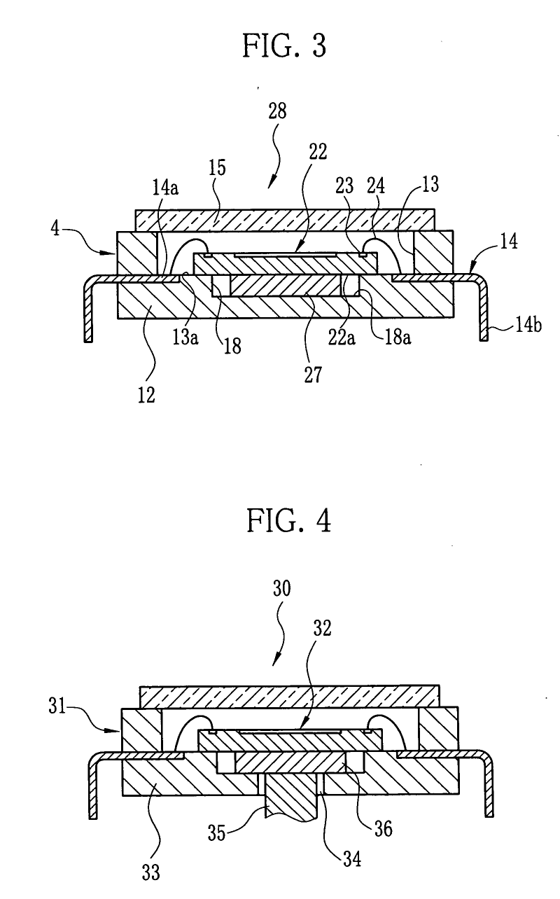

To solve this problem, a heat conductive plate 27 is placed in the second chip chamber 18 such that it makes contact with an under surface 22a of the image sensor chip 22 and the bottom surface 18a of the second chip chamber 18, as shown with a solid state imaging device 28 in FIG. 3. The heat conductive plate 27 is preferably made of a material with excellent heat conductivity. Instead, the heat conductive plate 27 may be a small image sensor chip judged as defective in a performance test. This method allows the effective use of otherwise discarded image sensor chips, and the cost of the solid state imaging devices is reduced accordingly. Moreover, the wastes can be reduced. Since the image sensor chips are silicon substrates which have good heat conductivity, they can produce a good heat radiation effect when used as the heat conductive plate.

A hollow package 31 of a solid state imaging device 30, shown in FIG. 4, has a through hole 34 on an under surface of a package body 33. A heat conductive member 35 is then inserted into the through hole 34, and attached to an under surface of a heat conductive plate 36. With this configuration, the heat is dissipated more effectively than through the package body 33.

Although the above embodiments are explained with the solid state imaging device which has the image sensor chip in the hollow package, any kind of semiconductor chip, such as memory, can be contained in the hollow package. Even in this case, the hollow package accommodates the semiconductor chips of different sizes, and the cost of the semiconductor device is reduced consequently. Although the chip chamber is made to have two steps in the above embodiments, the chip chamber may have three and more steps. This configuration enables the hollow package to contain the chips of more different sizes, and the cost is further reduced.

In the above embodiments, the step-like chip chamber is formed to contain the image sensor chips of different sizes. However, the step-like chip chamber may be used for alignment of the image sensor chip in the optical axis direction. For example, an imaging optical system of the solid state imaging device is provided with an optical low pass filter (OLPF). Since the thickness of the OLPF is determined by pixel pitch of the image sensor chip, the optical length may change depending on the kind of the image sensor chip to be used. The change of the optical length leads to change an imaging plane position of the image sensor chip. In this case, the image sensor chip is placed in one of the chip chambers in a better imaging plane position.

As described so far, the present invention is not to be limited to the above embodiments, and all matter contained herein is illustrative and does not limit the scope of the present invention. Thus, obvious modifications may be made within the spirit and scope of the appended claims.

What is claimed is:

1. A hollow package for containing a semiconductor chip comprising:
a package body;
a recessed first chip chamber provided on a top surface of said package body;
a recessed second chip chamber provided on a bottom surface of said first chip chamber, either said first or second chip chamber containing said semiconductor chip;
connectors electrically connected to said semiconductor chip contained in either said first or second chip chamber; and
a cover attached on said top surface of said package body, and for sealing said first chip chamber.

2. A hollow package as claimed in claim 1, wherein said semiconductor chip is contained in either said first or second chip chamber according to the size of said semiconductor chip.

3. A hollow package as claimed in claim 1, wherein said second chip chamber is provided in the center of said bottom surface of said first chip chamber.

4. A hollow package as claimed in claim 1, wherein said connectors are leads inserted in said package body, one end of said leads being exposed on said bottom surface of said first chip chamber whereas the other end of said leads extending outside said package body.

5. A hollow package as claimed in claim 1, wherein said semiconductor chip is an image sensor chip for converting optical images into electrical signals, and wherein said cover is made of a transparent material.

6. A hollow package as claimed in claim 1, further comprising:
a first heat conductor contained in said second chip chamber, said first heat conductor being in contact with both an under surface of said semiconductor chip die-bonded in said first chip chamber and a bottom surface of said second chip chamber.

7. A hollow package as claimed in claim 6, wherein said first heat conductor is a defective semiconductor chip.

8. A hollow package as claimed in claim 6, further comprising:
a through hole for heat radiation penetrating to said bottom surface of said second chip chamber; and
a second heat conductor inserted in said through hole and being in contact with said first heat conductor.

9. A semiconductor device comprising:
a package body;
a recessed first chip chamber provided on a top surface of said package body;
a recessed second chip chamber provided on a bottom surface of said first chip chamber;
a semiconductor chip contained in either said first or second chip chamber;
connectors electrically connected to said semiconductor chip; and
a cover attached on said top surface of said package body, and for sealing said first chip chamber.

10. A semiconductor device as claimed in claim 9, wherein said semiconductor chip is an image sensor chip for converting optical images into electrical signals, and wherein said cover is made of a transparent material.
